(19) United States
(12) Patent Application Publication
(10) Pub. No.: US 2026/0105766 A1
(43) Pub. Date: Apr. 16, 2026

(54) VISION FOUNDATION MODELS FOR LARGE SCALE POINT CLOUD ANALYSIS, SEGMENTATION, AND CLASSIFICATION

(71) Applicant: Autodesk, Inc., San Francisco, CA (US)

(72) Inventors: Li Jiang, Singapore (SG); Daxuan Ren, Singapore (SG); Pradit Mittrapiyanuruk, BANGKOK (TH)

(73) Assignee: Autodesk, Inc., San Francisco, CA (US)

(21) Appl. No.: 19/319,183

(22) Filed: Sep. 4, 2025

Related U.S. Application Data
(60) Provisional application No. 63/706,825, filed on Oct. 14, 2024.

(51) Int. Cl. G06V 20/70; G01S 17/894; G06F 30/13; G06T 17/00; G06V 10/26; G06V 10/764

(52) U.S. Cl. CPC G06V 20/70; G06F 30/13; G06T 17/00; G06V 10/267; G06V 10/764; G01S 17/894; G06T 2210/56

(57) ABSTRACT

A method and system provide the ability to segment a first point cloud. The first point cloud is rendered into multiple two-dimensional (2D) images. The images are segmented to generate a semantic segmentation mask. The images are then backprojected into a 3D classified point cloud. The classified point cloud is segmented into geometric segments and voting is performed for each segment to determine the majority classification and reassign minority classifications. A final point cloud is then exported as a segmented classified point cloud.

### CROSS-REFERENCE TO RELATED APPLICATIONS

This application claims the benefit under 35 U.S.C. Section 119(e) of the following co-pending and commonly-assigned U.S. provisional patent application(s), which is/are incorporated by reference herein:

Provisional Application Ser. No. 63/706,825, filed on Oct. 14, 2024, with inventor(s) Li Jiang, Daxuan Ren, and Pradit Mittrapiyanuruk, entitled “Vision Foundation Models for Large Scale Point Cloud Analysis, Segmentation, and Classification,” attorneys' docket number 30566.0634USP1.

### BACKGROUND OF THE INVENTION

### 1. Field of the Invention

The present invention relates generally to point cloud processing, and in particular, to a method, system, apparatus, and article of manufacture for semantically segmenting a point cloud.

### 2. Description of the Related Art

(Note: This application references a number of different publications as indicated throughout the specification by reference numbers enclosed in brackets, e.g., [x]. A list of these different publications ordered according to these reference numbers can be found below in the section entitled “References.” Each of these publications is incorporated by reference herein.)

Developing an efficient and highly generalizable method for point cloud semantic segmentation is still a challenging task. This is due to two main reasons. First, there is currently no end-to-end point cloud backbone that can handle billions of points without down-sampling. Secondly, there is lack of annotated datasets that are large enough to reach the scale of billions. Thus, there is a need to perform point cloud semantic segmentation for large arbitrarily-sized point clouds in an automated manner. To better understand the problems of the prior art, a description of prior art point clouds and segmentation may be useful.

Point clouds have emerged as the standard format for scene capture, visualization, and processing. Recent advancements in LiDAR (Light Detection and Ranging) scanner technologies have enabled the generation of large-scale point clouds comprising billions of points.

Recently, point cloud analysis, segmentation, and classification have relied on end-to-end models. While these methods yield promising results on synthetic datasets or smaller-scale real-life captures, they often falter in industrial scenarios where point clouds can contain billions of points. This discrepancy presents a significant challenge, bridging the gap between academic research and practical, large-scale applications.

In the realm of 2D computer vision, vision foundation models such as Contrastive Language-Image Pre-training (CLIP) and Segment Anything Model (SAM) have revolutionized the field. These models, trained on billions of internet-sourced images, have demonstrated remarkable generalization capabilities due to the scale of their training datasets and the capacity of large models. However, in 3D computer vision, the hurdles of acquiring, processing, and storing vast datasets—let alone the prohibitive costs of manually annotating them—pose significant challenges. Therefore, the potential of leveraging trained 2D vision foundation models for large-scale 3D point cloud analysis warrants further exploration.

Foundation Models-Foundation models—[15] have brought a paradigm shift in deep learning. These large, pre-trained models, built on extensive datasets, offer remarkable versatility across a range of tasks. A prime example is Chat-GPT [3], which has significantly advanced the field of natural language processing. Beyond language-specific models, multimodal foundation models [1] have also garnered substantial interest. They are pivotal in applications spanning from sophisticated image understanding to dynamic text conditioned image generation. Among these, CLIP [10] stands out for its unique capability to extract and align information from both images and texts into a unified embedding space, facilitating a deeper interconnectedness between visual and textual data.

Segment Anything Model (SAM)-SAM—[5], developed by META™, is a groundbreaking vision foundation model designed for class-agnostic image segmentation. It supports various types of prompts, including bounding boxes, points, rough masks, and text inputs. SAM's architecture features a robust image encoder paired with a streamlined decoder, enabling quick inference with multiple prompt types. The model is trained on a substantial in-house dataset comprising 11 million images and 1.1 billion masks. SAM demonstrates exceptional segmentation accuracy with geometric prompts. However, META™ has not released the text encoder module, which limits its capabilities for text-driven image segmentation.

Open Vocabulary Object Detection Models—GroundingDINO [6] (DETR [Detection Transformer] with Improved DeNoising Anchor Boxes) exemplifies the evolution of object detection models by incorporating language into traditionally closed vocabulary systems for open-set generalization. During its inference process, Grounding DINO takes an image and a language prompt, outputting bounding boxes along with probability logits corresponding to each box relative to tokens in the language prompt. This innovative approach allows users to identify virtually any object within an image using text descriptions, vastly expanding the model's utility and applicability.

Point cloud Backbones—Point Cloud Semantic Segmentation has rapidly evolved, with pivotal contributions shaping the field. Early models like PointNet [8] and PointNet++[9] laid the groundwork by directly processing point clouds and capturing local structures. Graph-based approaches, such as DGCNN (dynamic graph convolutional neural network) [13], further refined segmentation by leveraging dynamic graphs to understand geometric relationships. Voxel-based methods like 3D UNet [4] brought the familiarity of 2D image processing techniques, albeit with high computational demands due to point cloud sparsity. More recent innovations, like hybrid models (e.g., PVCNN (point voxel CNN) [7]) and attention-based methods (e.g., Point Transformer), merge the benefits of different approaches and introduce dynamic weighting for nuanced segmentation. Despite these advances, challenges remain in handling large-scale data and varying densities, pointing towards future research in efficient architectures and cross-modal learning techniques.

Point cloud segmentation with geometric properties—In the realm of point cloud segmentation, methods like Region Growing [12] and RANSAC have been foundational. Region Growing is widely used for its effectiveness in segmenting homogeneous regions. It starts from seed points and aggregates neighboring points that meet certain criteria, like curvature or normal consistency, enabling it to adapt to various surface geometries. On the other hand, RANSAC [2, 11] (Random Sample Consensus) excels in identifying geometric primitives like planes or spheres within noisy data, making it ideal for extracting structured objects from unstructured point clouds.

As described above, some of the prior art approaches utilize predefined manual rules based on heuristic model/approach (e.g., if it is a large vertical plane, it is probably a wall inside of a building, and if there is a flat horizontal plane of points, it is probably a floor). While other prior art end-to-end approaches utilize an ML model that inputs a set of points and generates a set of classifications, such approaches are unable to process large datasets as the number of points to process exceed GPU hardware capabilities. Yet other prior art systems utilize a closed vocabulary approach that is based on a small limited vocabulary (e.g., the classification is limited to a particular vocabulary specific to a particular type of diagram such as interior or pipes) and cannot be used on images that don't fall within the predefined set of objects/classes.

In view of the above, the prior art methodologies fail to provide (1) the ability to handle billions of points without down-sampling, and (2) provide an annotated dataset that is large enough to reach the scale of billions (i.e., the ability to acquire, process, and store such datasets that avoids the prohibitive costs of manually annotating them).

### SUMMARY OF THE INVENTION

To address these limitations, embodiments of the invention provide a training free open vocabulary point cloud segmentation method that supports arbitrary point cloud sizes and exhibits strong generalization ability. Embodiments of the invention integrate 2D vision foundation into point cloud semantic segmentation, with careful design choices to ensure a modular pipeline that can be adapted easily to the rapid advancements in 2D vision foundation. The effectiveness of embodiments of the invention may be demonstrated using multiple large-scale datasets and extensive visualizations, including an example on how to leverage existing ML research as a component on solving real life engineering problems. More specifically, embodiments leverage recent advancements in 2D image modelling to solve real-life 3D problems using machine learning without any training.

### BRIEF DESCRIPTION OF THE DRAWINGS

Referring now to the drawings in which like reference numbers represent corresponding parts throughout:

FIG. 1 illustrates an overview of the five stages of point cloud processing in accordance with one or more embodiments of the invention;

FIG. 2 illustrates the logical flow for large scale point cloud analysis, segmentation, and classification in accordance with one or more embodiments of the invention;

FIG. 3 showcases rendered images from point clouds in accordance with one or more embodiments of the invention;

FIG. 4 illustrates object detection results and segmentation masks in accordance with one or more embodiments of the invention;

FIG. 5 illustrates an exemplary point cloud segmentation result by back projecting one segmented image in accordance with one or more embodiments of the invention;

FIG. 6 illustrates an exemplary point cloud segmentation using region growing in accordance with one or more embodiments of the invention;

FIG. 7 illustrates a visual comparison of refined classification results without segmentation voting and with segmentation voting in accordance with one or more embodiments of the invention;

FIG. 8 is an exemplary hardware and software environment used to implement one or more embodiments of the invention; and

FIG. 9 schematically illustrates a typical distributed/cloud-based computer system in accordance with one or more embodiments of the invention.

### DETAILED DESCRIPTION OF THE INVENTION

In the following description, reference is made to the accompanying drawings which form a part hereof, and which is shown, by way of illustration, several embodiments of the present invention. It is understood that other embodiments may be utilized and structural changes may be made without departing from the scope of the present invention.

### Overview

Embodiments of the invention address the challenge of processing and analyzing LiDAR scan data. The initial step involves the registration of multiple LiDAR scans into a cohesive, structured global scene, which is subsequently stored as a ReCap project. The primary objective is to develop an automated system capable of thoroughly analyzing this integrated scene. This system is tasked with generating a comprehensive list of object class names present within the scene. Following this classification phase, the next crucial step involves the segmentation of the point cloud. The segmentation process aims to meticulously divide the point cloud into distinct segments, each associated with the relevant class labels identified earlier. The ultimate goal is to accurately assign and return the class label for each individual segment, thereby facilitating a detailed and categorized understanding of the scanned environment.

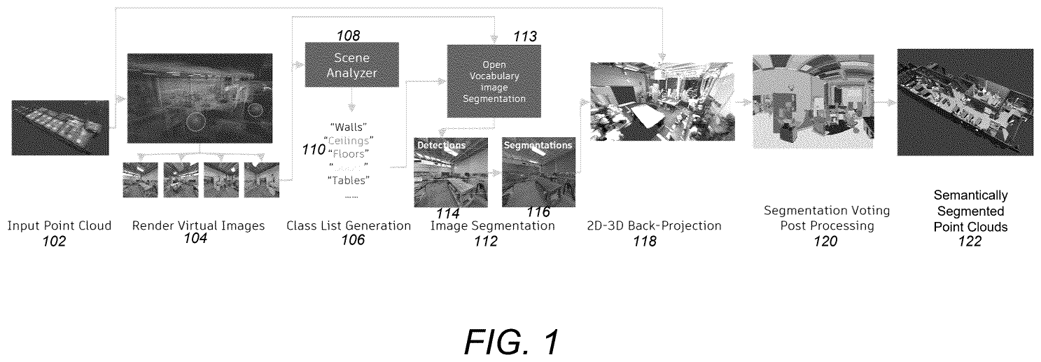

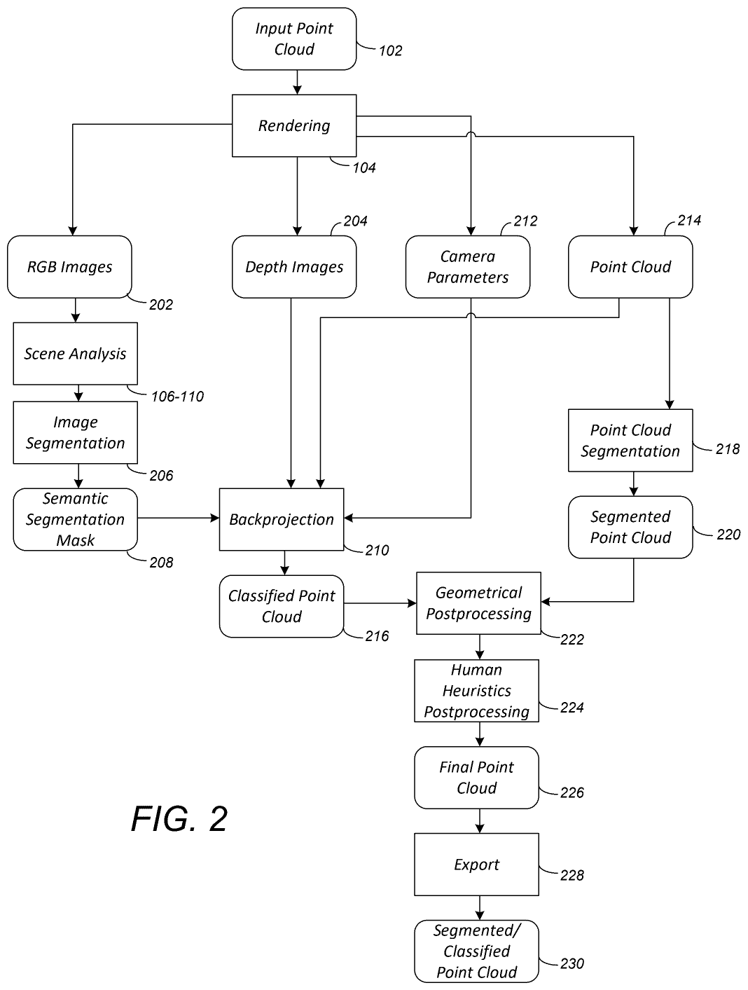

In view of the embodiments, the methodology of embodiments of the invention encompasses five distinct stages, each integral to the overall process. FIG. 1 illustrates an overview of this process in accordance with one or more embodiments of the invention. The stages are as follows: (1) Virtual Image Acquisition, where the (input) point cloud 102 is rendered into 2D (virtual) images 104; (2) Scene Analysis/Class List Generation 106, where a scene analyzer 108 automatically/autonomously generates a list of class names 110; (3) Open Vocabulary Image Segmentation 112/113, where the images 104 are segmented into semantically meaningful parts (e.g., detections 114 and segmentations 116); (4) Image and Point Cloud Back Projection 118, in which the segmented images 116 are aligned and projected onto the point cloud; and (5) (Segmentation Voting) Post-Processing 120 (with geometric heuristics), where final adjustments and refinements are made resulting in semantically segmented point clouds 122. The ensuing sections will provide a detailed exploration of each stage while referencing FIG. 2 which provides a more detailed logical flow for large scale point cloud analysis, segmentation, and classification.

### Virtual Image Acquisition

### Virtual Camera Placement

Referring to FIG. 2, the first step is to receive/acquire point cloud input 102 (also referred to herein as the first point cloud). Such point cloud input may include additional information needed for further processing. For example, the point cloud input may include registration information such as the scanner location, rotations, and points. In one or more embodiments, the point cloud input may be received/acquired in (or processed into) a proprietary format such as the RECAP PROJECT FORMAT™ (RCP) available from the assignee of the present invention. In one or more embodiments of the invention, the point cloud input 102 may be acquired using LiDAR (e.g., in which depth image data for each point in the point cloud may be known).

In the case of structured scenes (e.g., human-made settings like cities, roads, and buildings that have objects with inherent order and predictable layouts), determining the LiDAR locations is straightforward, enabling embodiments of the invention to accurately set the virtual camera's center at fixed points (e.g., based on the LiDAR locations).

In the case of unstructured scenes (e.g., challenging terrains such as dense forests, rough landscapes, or unpredictable natural formations), the process of computing the camera's placement may demand a more innovative approach. Once the (virtual) camera's position is established, the virtual camera may be rotated along the XY plane at predetermined intervals, incorporating random tilts. This technique is designed to maximize/improve the coverage of the virtual camera's view frustum, ensuring comprehensive scene capture.

### Virtual Image Rendering 104

Once the first point cloud 102 is input/acquired, the next step is to render the first point cloud into multiple two-dimensional (2D) images. Although image rendering 104 can utilize off-the-shelf point cloud renderers, such output is often suboptimal for specific requirements of embodiments of the invention. This inadequacy arises because these general-purpose renderers do not fully exploit the additional information inherent in point cloud scans. As described above, point cloud input 102 may possess several key pieces of information that enhance the rendering capability: (1) Access to individual point clouds acquired from each scanner location is available; (2) point cloud input 102 may have pre-baked shading colors; (3) point cloud scans may be stored individually in spherical coordinates, represented as panoramic TIFF (tag image file format) images where each pixel corresponds to a point.

Utilizing this information, embodiments of the invention provide a custom renderer (i.e., that is tailored to the needs of embodiments of the invention) that performs rendering 104. The renderer renders the point cloud input 102 into one or more RGB (red green blue) images 202 and one or more depth images 204. Further, the rendered 2D images may also include camera parameters.

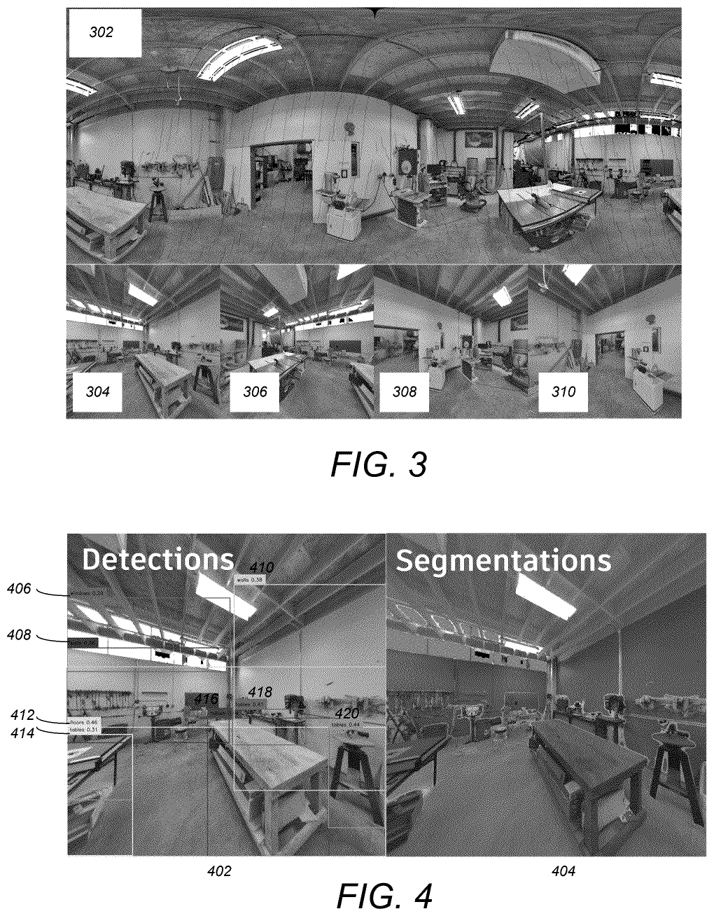

Specifically, for each virtual camera, the rendering 104 transforms panoramic images back into point clouds, then a camera projection matrix is applied to project these points onto image coordinates. Subsequently, image interpolation is performed to fill any gaps, ensuring a seamless visual output. It's noteworthy that the spherical coordinate system of the points obviates the need for a Z-buffer to track point occlusions. FIG. 3 showcases rendered images 202-204 in accordance with one or more embodiments of the invention. More specifically, FIG. 3 illustrates an example of rendered images from pointcloud input 102. A rendered spherical RGB image 202 is illustrated at 302 and 304-310 illustrate rendered perspective images from different virtual cameras.

A similar approach may be applied to generate depth maps/images 204.

### Scene Analysis/Class List Generation 106-110

While models of embodiments of the invention are designed to accept a wide range of class names specified by users, manually inputting these names can be a cumbersome task. To streamline this process, a module may automatically/autonomously generate a list of potential class names for users to select and modify as needed. This is achieved through the following procedure: a set of virtual images (i.e., RGB images 202 and/or depth images 204) are first processed using a recognition model (e.g., the Recognize Anything Model (RAM) [14]), which assigns several tags to each of the multiple 2D images. Upon completion of this tagging process for all images, these tags are aggregated (i.e., into an aggregated tag list). The final list of class names 110 is then compiled (from the aggregated tag list) based on tag frequencies, word similarities, and parts of speech. This method significantly reduces user effort and enhances the efficiency of the classification process.

### Open Vocabulary Image Segmentation 206

After rendering 104 into 2D images, the multiple 2D images are segmented (at 206) to generate a semantic segmentation mask 208 (where the semantic segmentation mask consists of a per pixel label for each pixel of the multiple 2D images).

Embodiments of the invention may utilize an image segmentation model (e.g., an open vocabulary image segmentation model) that segments 206 the RGB images 202 to generate the segmentation mask 208. The issue is how to segment the images 202 based on a user text input/prompt (e.g., natural language prompt) that is not limited to a particular library/set of classifications (i.e., that can utilize an open vocabulary). Vision foundation models like SAM [5] theoretically have the capability to directly process text prompts. However, in practical applications, this functionality is limited as META™ has not released the text prompt encoder for SAM. To address this gap, embodiments of the invention provide a two-step approach specifically tailored for open vocabulary image segmentation 206: (1) Open Vocabulary Object Detection; and (2) Segmentation Mask Generation.

### Open Vocabulary Object Detection

In view of the above, the segmentation of the multiple 2D images detects one or more objects using an open vocabulary image segmentation model. Inputs to the model may include the multiple 2D images and a text prompt. The model then generates a bounding box for each detected object. Exemplary embodiments may employ GroundingDINO [6] for object detection in images (e.g., RGB images 202) using open vocabulary, a method selected after rigorous testing. Comparative analyses with various open vocabulary object detection models revealed that GroundingDINO provides superior generalization capabilities specifically for scanned images.

### Segmentation Mask Generation

After the model generates detection bounding boxes, these are used as box prompts for a segmenting model. For example, the multiple 2D images and bounding boxes may be are used by a segmenting model to produce individual pixel masks. In such embodiments, inputs to the segmenting model may be the bounding boxes (e.g., as box prompts) and each individual pixel mask highlights a most prominent detected object within each bounding box. For example, in one or more embodiments, the segmenting model may be the Segment Anything Model (SAM). SAM processes the provided image and bounding box to produce a pixel mask, highlighting the most prominent object within each box. Subsequently, each (individual pixel) mask is associated with its corresponding text prompt. Following the processing of all bounding boxes, the individual pixel masks are amalgamated to form a comprehensive global semantic segmentation map/mask 208. In this regard, the segmentation mask 208 may consists of a per pixel label (e.g., pixel A is a floor pixel and pixel B is a wall pixel).

FIG. 4 illustrates object detection results at 402 and segmentation masks 404 in accordance with one or more embodiments of the invention. The object detection results 402 include bounding boxes with text 406-420 (i.e., windows 406, walls 408 and 410, floors 412, and tables 414, 416, 418, and 420) identifying the most prominent object within each bounding box. The detected objects 406-420 are then used to generate a pixel (segmentation)mask 404 for each detected object (reflected by different colors/shading).

### Image-Point Cloud Back-projection 210

Building upon the previous steps where semantic masks 208 were generated for each virtual image, the next goal is to extend this 2D segmentation into the 3D domain. This is achieved by backprojecting the multiple 2D images into a second point cloud. The second point cloud is a 3D point cloud that is classified such that every point of the classified 3D point cloud includes a classification label based on the per pixel label from the semantic segmentation mask 208.

In view of the above, the scene's point cloud 214 may be projected/backprojected using the projection matrix associated with each virtual camera (i.e., camera parameters 212), while recording the depth (i.e., from depth images 204) of each projected point. The rendered depth is then compared with that obtained from the virtual image 202. If the depth discrepancy for a point falls within a specified threshold (e.g., 5 cm), a class candidate is assigned to that point. This candidate class is identified by correlating the pixel coordinates of the projected point to the corresponding class ID on the semantic segmentation map of the virtual image 202.

After processing all the virtual images 202, a classified point cloud 216 is acquired where each point is associated with a list of potential class candidates. In other words, with the camera parameters 212, embodiments of the invention back project 210 from 2D back to 3D. Once back projected, every single point has a classification label because every point that appears on a 2D image can be projected resulting in a 3D classified point cloud 216. To determine the final class label for each point, a majority voting mechanism is employed. For enhanced accuracy, a confidence-weighted majority vote, based on mask logits, is an alternative approach. However, embodiments of the invention may opt against this method due to its higher memory and computational requirements.

Backprojecting 210 every point from the point cloud 214 to each virtual image is inherently time-consuming. To address this, a specialized data structure akin to Bounding Volume Hierarchy (BVH) may be utilized. This structure significantly enhances efficiency by eliminating the need to project points unnecessarily, thereby substantially improving the runtime of the backprojection step 210.

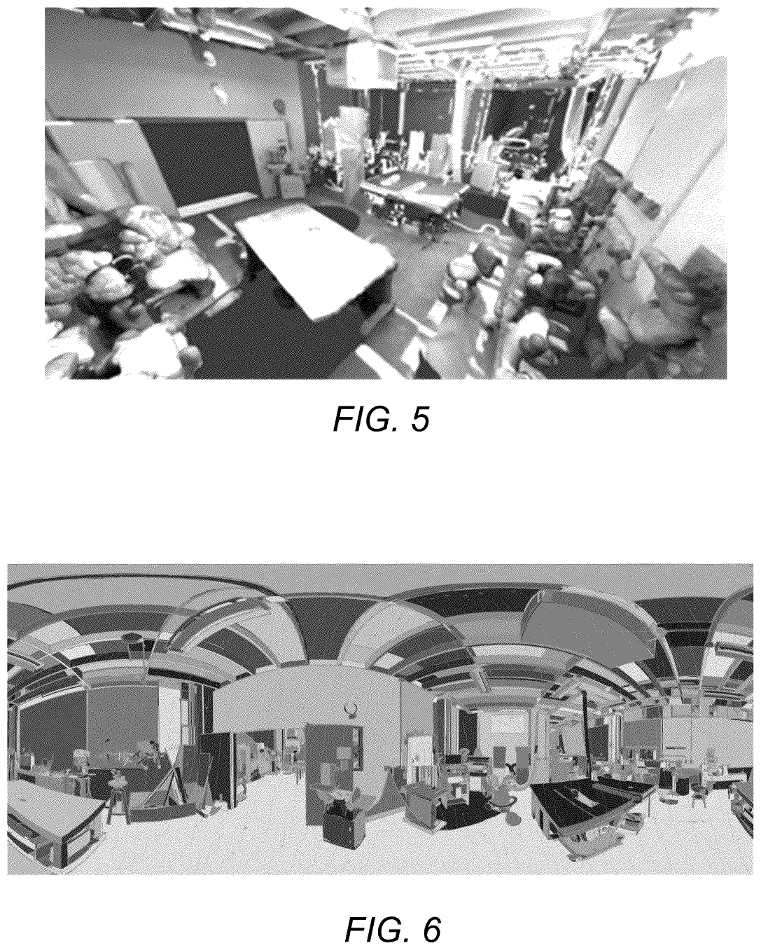

FIG. 5 illustrates an exemplary point cloud segmentation result by back projecting 210 one segmented image.

### Post Processing

Following the initial segmentation 206 and classification (i.e., the back projection 210), the result is a semantically segmented/classified point cloud 216. However, due to the independent processing of each point and potential inaccuracies in image segmentation 206, some noise remains in the point cloud 216. To address this, embodiments of the invention introduce a post-processing step 222 that utilizes geometric cues. This additional phase 222 is designed to refine and enhance the segmentation 206 and classification 216 results, thereby reducing the noise and improving overall accuracy.

### Geometry Segmentation 222

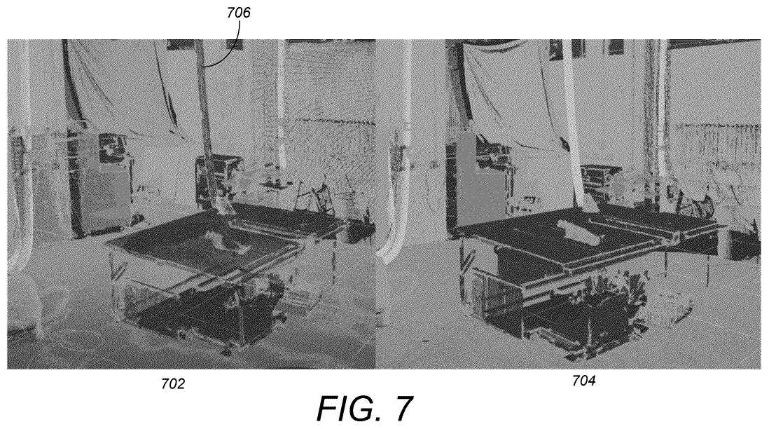

To address the inaccuracies, the point cloud 214 may also be segmented geometrically at 218 (i.e., resulting in geometrically segmented point cloud 220 [e.g., consisting of geometric segments]). In particular, beyond the realm of deep learning-based semantic segmentation, there exists distinct approaches to point cloud segmentation 218 that predates the deep learning era. These approaches rely on handcrafted features and heuristics to segment 218 point 214 clouds into geometrically meaningful parts. Among the various methods developed, region growing segmentation [12] stands out. It is widely adopted in both industry and the research community due to its intuitive concept and robust performance. An example of a point cloud segmented using this method (i.e., of region growing) (in accordance with one or more embodiments of the invention) can be seen in FIG. 6.

Embodiments of the invention have incorporated region growing into the processing pipeline, and segment 218 the point cloud 214 into geometrically meaningful segments (i.e., outputting segmented point cloud 220).

To further refine the classification results, a majority voting process (referred to herein as geometric segmentation voting) is applied/performed within each segment, leading to significantly improved outcomes. For example, if a flat piece contains 80% votes of a floor classification label and 20% of some other random classification, the majority may be utilized to determine that the whole piece should have the floor classification. In this regard, embodiments of the invention may iterate through every segment in the segmented point cloud 220 gathering classification labels associated with that segment and conducting a majority vote to determine what most of the points were classified as. In other words, for each of the geometric segments, a majority classification label is determined wherein the majority classification label has a majority compared to minority classification labels of the gathered classification labels.

Once the majority has been determined, those points having a minority classification are reassigned to the majority classification label. Such an approach serves to reject outliers and attempts to refine/correct any mistakes in the classification. A visual comparison of these results (in accordance with one or more embodiments of the invention) can be seen in FIG. 7. In particular, image 702 illustrates refined classification results without segmentation voting while image 704 illustrates refined mage segmentation with segmentation voting. It may also be noted that image 702 includes black points 706 on the pipe which has been removed in image 704 due to the segmentation voting.

### Human Heuristic Post-processing 224

Instead of relying solely on neural networks for point cloud classification, embodiments of the invention enhance the classification pipeline by performing heuristic post processing by incorporating predefined rules (e.g., human defined rules) as a safeguard (i.e., human heuristics post processing 224). Thus, one or more geometric based classification rules are determined. These rules are applied on a per segment basis, taking into account the segment's geometric properties (i.e., from geometrical postprocessing 222), such as normals and curvatures. In other words, for each of the geometric segments, the rule is evaluated. For instance, a rule may provide that a segment of the point cloud classified as “wall” should be perpendicular to the ground. Such a rule helps filter out horizontal segments that may have been incorrectly classified as walls. Similar rules may also be enforced for other classes, including “floors,” “ceilings,” “pipes,” “roofs,” “doors,” “windows,” “ground,” “roads,” and more. Segments that do not meet the rule criteria are labeled as “invalid” and undergo an additional round of segmentation voting, where the “invalid” class does not contribute. In other words, the rule evaluation may determine that at least one of the majority classification labels violates the rule. Based on the violation, the violating majority classification may be labeled as invalid and the geometric segmentation voting then then be repeated where the invalid majority classification does not contribute in the voting.

### Export

Once the post processing 222 and 224 have been completed, the final point cloud 226 (with the reassigned minority classification labels) may be exported 228 (e.g., for storage/retrieval/use) as a segmented/classified point cloud 230. For example, upon completing steps 102-104 and 202-224, the processed point cloud 226 can be exported 228 to RECAP PRO™, RECAP CLOUD VIEWER™, or other products. This integration facilitates further visualization and editing, significantly accelerating projects/use. For example, the final point cloud 226 may be visualized as a 3D model of a real world environment in a computer-aided design (CAD) application (e.g., where the visualization may consist of a floor plan for a structure).

### Alternative Embodiments

Embodiments of the invention may have some limitations. For example, the object detection followed by segmentation may have limited capacity to handle some corner cases, i.e. especially when the objects are tilted diagonally. Further, the back-projection 210 may be quite slow when the number of scans become large. In addition, the point cloud segmentation 218 with region growing is a global procedure and may require quite extensive RAM to operate.

Additional embodiments may improve the run time and accuracy of using: distributed parallel processing; a serverless deployment with extensive parallelization; fine tuning on the 2D image model for better segmentation accuracy; and smart camera placement and rendering for unstructured and sparse point clouds.

### Software and Hardware Architecture

One advantage of a pipeline of embodiments of the invention lies in its modular structure, where each of the five steps (i.e., steps 104, 106, 112/113, 118, and 120) acts as a blueprint for leveraging 2D image-based segmentation in 3D point cloud processing. The independence of each component allows for flexible updates and enhancements. For instance, different rendering modules may be selected for structured or unstructured scans, and the 2D semantic segmentation module can be seamlessly replaced with newer versions as they become available.

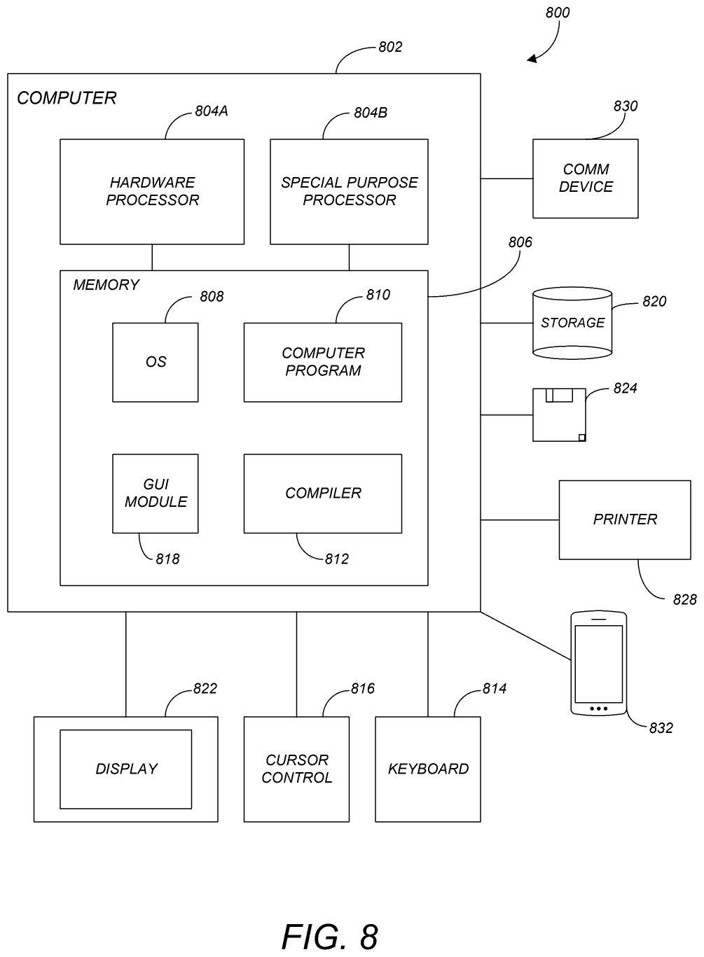

FIG. 8 is an exemplary hardware and software environment 800 (referred to as a computer-implemented system and/or computer-implemented method) used to implement one or more embodiments of the invention. The hardware and software environment includes a computer 802 and may include peripherals. Computer 802 may be a user/client computer, server computer, or may be a database computer. The computer 802 comprises a hardware processor 804A and/or a special purpose hardware processor 804B (hereinafter alternatively collectively referred to as processor 804) and a memory 806, such as random access memory (RAM). The computer 802 may be coupled to, and/or integrated with, other devices, including input/output (I/O) devices such as a keyboard 814, a cursor control device 816 (e.g., a mouse, a pointing device, pen and tablet, touch screen, multi-touch device, etc.) and a printer 828. In one or more embodiments, computer 802 may be coupled to, or may comprise, a portable or media viewing/listening device 832 (e.g., an MP3 player, IPOD, NOOK, portable digital video player, cellular device, personal digital assistant, etc.). In yet another embodiment, the computer 802 may comprise a multi-touch device, mobile phone, gaming system, internet enabled television, television set top box, or other internet enabled device executing on various platforms and operating systems.

In one embodiment, the computer 802 operates by the hardware processor 804A performing instructions defined by the computer program 810 (e.g., a computer-aided design [CAD] application) under control of an operating system 808. The computer program 810 and/or the operating system 808 may be stored in the memory 806 and may interface with the user and/or other devices to accept input and commands and, based on such input and commands and the instructions defined by the computer program 810 and operating system 808, to provide output and results.

Output/results may be presented on the display 822 or provided to another device for presentation or further processing or action. In one embodiment, the display 822 comprises a liquid crystal display (LCD) having a plurality of separately addressable liquid crystals. Alternatively, the display 822 may comprise a light emitting diode (LED) display having clusters of red, green and blue diodes driven together to form full-color pixels. Each liquid crystal or pixel of the display 822 changes to an opaque or translucent state to form a part of the image on the display in response to the data or information generated by the processor 804 from the application of the instructions of the computer program 810 and/or operating system 808 to the input and commands. The image may be provided through a graphical user interface (GUI) module 818. Although the GUI module 818 is depicted as a separate module, the instructions performing the GUI functions can be resident or distributed in the operating system 808, the computer program 810, or implemented with special purpose memory and processors.

In one or more embodiments, the display 822 is integrated with/into the computer 802 and comprises a multi-touch device having a touch sensing surface (e.g., track pod, touch screen, smartwatch, smartglasses, smartphones, laptop or non-laptop personal mobile computing devices) with the ability to recognize the presence of two or more points of contact with the surface. Examples of multi-touch devices include mobile devices (e.g., IPHONE, ANDROID devices, WINDOWS phones, GOOGLE PIXEL devices, NEXUS S, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 802 according to the computer program 810 instructions may be implemented in a special purpose processor 804B. In this embodiment, some or all of the computer program 810 instructions may be implemented via firmware instructions stored in a read only memory (ROM), a programmable read only memory (PROM) or flash memory within the special purpose processor 804B or in memory 806. The special purpose processor 804B may also be hardwired through circuit design to perform some or all of the operations to implement the present invention. Further, the special purpose processor 804B may be a hybrid processor, which includes dedicated circuitry for performing a subset of functions, and other circuits for performing more general functions such as responding to computer program 810 instructions. In one embodiment, the special purpose processor 804B is an application specific integrated circuit (ASIC).

The computer 802 may also implement a compiler 812 that allows an application or computer program 810 written in a programming language such as C, C++, Assembly, SQL, PYTHON, PROLOG, MATLAB, RUBY, RAILS, HASKELL, or other language to be translated into processor 804 readable code. Alternatively, the compiler 812 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 810 accesses and manipulates data accepted from I/O devices and stored in the memory 806 of the computer 802 using the relationships and logic that were generated using the compiler 812.

The computer 802 also optionally comprises an external communication device such as a modem, satellite link, Ethernet card, or other device for accepting input from, and providing output to, other computers 802.

In one embodiment, instructions implementing the operating system 808, the computer program 810, and the compiler 812 are tangibly embodied in a non-transitory computer-readable medium, e.g., data storage device 820, which could include one or more fixed or removable data storage devices, such as a zip drive, floppy disc drive 824, hard drive, CD-ROM drive, tape drive, etc. Further, the operating system 808 and the computer program 810 are comprised of computer program 810 instructions which, when accessed, read and executed by the computer 802, cause the computer 802 to perform the steps necessary to implement and/or use the present invention or to load the program of instructions into a memory 806, thus creating a special purpose data structure causing the computer 802 to operate as a specially programmed computer executing the method steps described herein. Computer program 810 and/or operating instructions may also be tangibly embodied in memory 806 and/or data communications devices 830, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 802.

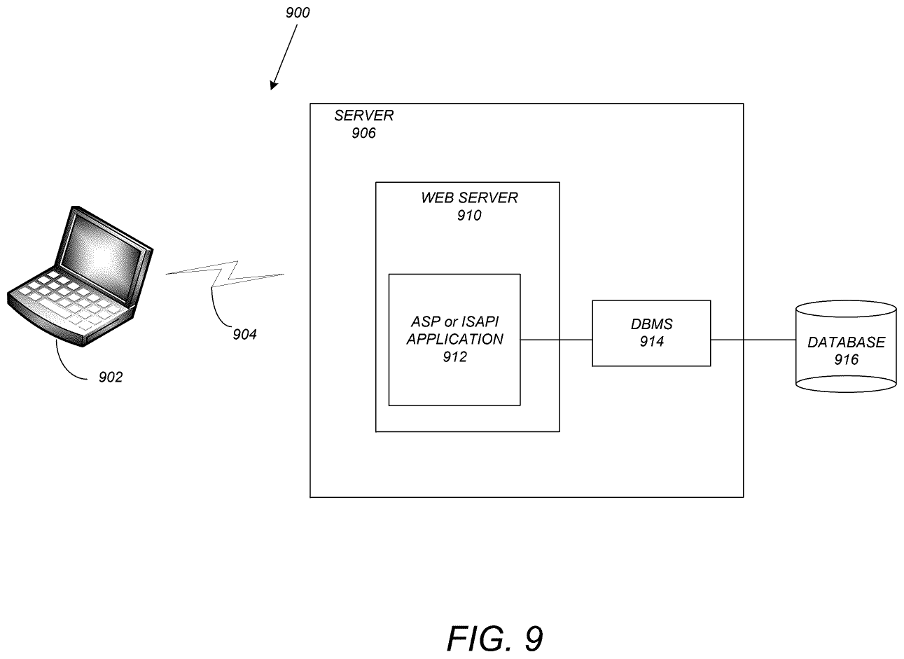

FIG. 9 schematically illustrates a typical distributed/cloud-based computer system 900 using a network 904 to connect client computers 902 to server computers 906. A typical combination of resources may include a network 904 comprising the Internet, LANs (local area networks), WANs (wide area networks), SNA (systems network architecture) networks, or the like, clients 902 that are personal computers or workstations (as set forth in FIG. 8), and servers 906 that are personal computers, workstations, minicomputers, or mainframes (as set forth in FIG. 8). However, it may be noted that different networks such as a cellular network (e.g., GSM [global system for mobile communications] or otherwise), a satellite based network, or any other type of network may be used to connect clients 902 and servers 906 in accordance with embodiments of the invention.

A network 904 such as the Internet connects clients 902 to server computers 906. Network 904 may utilize ethernet, coaxial cable, wireless communications, radio frequency (RF), etc. to connect and provide the communication between clients 902 and servers 906. Further, in a cloud-based computing system, resources (e.g., storage, processors, applications, memory, infrastructure, etc.) in clients 902 and server computers 906 may be shared by clients 902, server computers 906, and users across one or more networks. Resources may be shared by multiple users and can be dynamically reallocated per demand. In this regard, cloud computing may be referred to as a model for enabling access to a shared pool of configurable computing resources.

Clients 902 may execute a client application or web browser and communicate with server computers 906 executing web servers 910. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 902 may be downloaded from server computer 906 to client computers 902 and installed as a plug-in or ACTIVEX control of a web browser. Accordingly, clients 902 may utilize ACTIVEX components/component object model (COM) or distributed COM (DCOM) components to provide a user interface on a display of client 902. The web server 910 is typically a program such as MICROSOFT'S INTERNET INFORMATION SERVER.

Web server 910 may host an Active Server Page (ASP) or Internet Server Application Programming Interface (ISAPI) application 912, which may be executing scripts. The scripts invoke objects that execute business logic (referred to as business objects). The business objects then manipulate data in database 916 through a database management system (DBMS) 914. Alternatively, database 916 may be part of, or connected directly to, client 902 instead of communicating/obtaining the information from database 916 across network 904. When a developer encapsulates the business functionality into objects, the system may be referred to as a component object model (COM) system. Accordingly, the scripts executing on web server 910 (and/or application 912) invoke COM objects that implement the business logic. Further, server 906 may utilize MICROSOFT'S TRANSACTION SERVER (MTS) to access required data stored in database 916 via an interface such as ADO (Active Data Objects), OLE DB (Object Linking and Embedding DataBase), or ODBC (Open DataBase Connectivity).

Generally, these components 900-916 all comprise logic and/or data that is embodied in/or retrievable from device, medium, signal, or carrier, e.g., a data storage device, a data communications device, a remote computer or device coupled to the computer via a network or via another data communications device, etc.

Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 902 and 906 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 902 and 906. Embodiments of the invention are implemented as a software/CAD application on a client 902 or server computer 906. Further, as described above, the client 902 or server computer 906 may comprise a thin client device or a portable device that has a multi-touch-based display.

### Conclusion

This concludes the description of the preferred embodiment of the invention. The following describes some alternative embodiments for accomplishing the present invention. For example, any type of computer, such as a mainframe, minicomputer, or personal computer, or computer configuration, such as a timesharing mainframe, local area network, or standalone personal computer, could be used with the present invention.

In summary, embodiments of the invention provide an innovative, training free approach for large-scale point cloud semantic segmentation capable of processing billions of points. The modular design facilitates easy updates and enhancements, ensuring its adaptability and maintainability. Through various visualizations, the applicability of embodiments of the invention across diverse scene types may be demonstrated, highlighting its generalization capabilities.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

### REFERENCES

[1] Muhammad Awais, Muzammal Naseer, Salman Khan, Rao Muhammad Anwer, Hisham Cholakkal, Mubarak Shah, Ming-Hsuan Yang, and Fahad Shahbaz Khan. Foundational models defining a new era in vision: A survey and outlook. arXiv preprint arXiv: 2307.13721, 2023.

[2] Daniel Barath and Jiří Matas. Graph-cut ransac. In Proceedings of the IEEE conference on computer vision and pattern recognition, pages 6733-6741, 2018.

[3] Tom Brown, Benjamin Mann, Nick Ryder, Melanie Subbiah, Jared D Kaplan, Prafulla Dhariwal, Arvind Neelakantan, Pranav Shyam, Girish Sastry, Amanda Askell, et al. Language models are few-shot learners. Advances in neural information processing systems, 33:1877-1901, 2020.

[4] Özgün Çiçek, Ahmed Abdulkadir, Soeren S Lienkamp, Thomas Brox, and Olaf Ronneberger. 3d u-net: learning dense volumetric segmentation from sparse annotation. In Medical Image Computing and Computer-Assisted Intervention-MICCAI 2016:19th International Conference, Athens, Greece, October 17-21, 2016, Proceedings, Part II 19, pages 424-432. Springer, 2016.

[5] Alexander Kirillov, Eric Mintun, Nikhila Ravi, Hanzi Mao, Chloe Rolland, Laura Gustafson, Tete Xiao, Spencer Whitehead, Alexander C Berg, Wan-Yen Lo, et al. Segment anything. arXiv preprint arXiv:2304.02643, 2023.

[6] Shilong Liu, Zhaoyang Zeng, Tianhe Ren, Feng Li, Hao Zhang, Jie Yang, Chunyuan Li, Jianwei Yang, Hang Su, Jun Zhu, et al. Grounding dino: Marrying dino with grounded pre-training for open-set object detection. arXiv preprint arXiv:2303.05499, 2023.

[7] Zhijian Liu, Haotian Tang, Yujun Lin, and Song Han. Pointvoxel cnn for efficient 3d deep learning. Advances in Neural Information Processing Systems, 32, 2019.

[8] Charles R Qi, Hao Su, Kaichun Mo, and Leonidas J Guibas. Pointnet: Deep learning on point sets for 3d classification and segmentation. In Proceedings of the IEEE conference on computer vision and pattern recognition, pages 652-660, 2017.

[9] Charles Ruizhongtai Qi, Li Yi, Hao Su, and Leonidas J Guibas. Pointnet++: Deep hierarchical feature learning on point sets in a metric space. Advances in neural information processing systems, 30, 2017.

[10] Alec Radford, Jong Wook Kim, Chris Hallacy, Aditya Ramesh, Gabriel Goh, Sandhini Agarwal, Girish Sastry, Amanda Askell, Pamela Mishkin, Jack Clark, et al. Learning transferable visual models from natural language supervision. In International conference on machine learning, pages 8748-8763. PMLR, 2021.

[11] Ruwen Schnabel, Roland Wahl, and Reinhard Klein. Efficient ransac for point-cloud shape detection. In Computer graphics forum, pages 214-226.Wiley Online Library, 2007.

[12] Alain Tremeau and Nathalie Borel. A region growing and merging algorithm to color segmentation. Pattern recognition, 30(7):1191-1203, 1997.

[13] Yue Wang, Yongbin Sun, Ziwei Liu, Sanjay E Sarma, Michael M Bronstein, and Justin M Solomon. Dynamic graph cnn for learning on point clouds. ACM Transactions on Graphics (tog), 38(5):1-12, 2019.

[14] Youcai Zhang, Xinyu Huang, Jinyu Ma, Zhaoyang Li, Zhaochuan Luo, Yanchun Xie, Yuzhuo Qin, Tong Luo, Yaqian Li, Shilong Liu, et al. Recognize anything: A strong image tagging model. arXiv preprint arXiv:2306.03514, 2023.

[15] Ce Zhou, Qian Li, Chen Li, Jun Yu, Yixin Liu, Guangjing Wang, Kai Zhang, Cheng Ji, Qiben Yan, Lifang He, et al. A comprehensive survey on pretrained foundation models: A history from bert to chatgpt. arXiv preprint arXiv:2302.09419, 2023.

What is claimed is:

1. A computer-implemented method for segmenting a first point cloud, comprising:
(a) acquiring the first point cloud;
(b) rendering the first point cloud into multiple two-dimensional (2D) images;
(c) segmenting the multiple 2D images to generate a semantic segmentation mask, wherein the semantic segmentation mask comprises a per pixel label for each pixel of the multiple 2D images;
(d) backprojecting the multiple 2D images into a second point cloud, wherein:
(i) the second point cloud comprises a three-dimensional (3D) point cloud;
(ii) the second point cloud comprises a classified point cloud;
(iii) every point of the classified point cloud comprises a classification label based on the per pixel label from the semantic segmentation mask;
(e) segmenting the classified point cloud into geometric segments;
(f) performing geometric segmentation voting comprising:
(i) iterating through each of the geometric segments;
(ii) for each of the geometric segments, gathering the classification labels associated with that geometric segment;
(iii) for each of the geometric segments, determining a majority classification label, wherein the majority classification label has a majority
compared to minority classification labels of the gathered classification labels;
(iv) reassigning minority classification labels to the majority classification label; and
(g) exporting a final point cloud with the reassigned minority classification labels as a segmented classified point cloud.

2. The computer-implemented method of claim 1, wherein:
the point cloud is acquired from multiple LiDAR (light detection and ranging) scans; and
the point cloud comprises depth image data for each point in the point cloud.

3. The computer-implemented method of claim 2, wherein:
the first point cloud is for a structured scene;
LiDAR locations are known;
a virtual camera's center is set at fixed points based on the LiDAR locations.

4. The computer-implemented method of claim 2, wherein:
the first point cloud is for an unstructured scene;
determining a virtual camera's position; and
rotating the virtual camera along an XY plane at predetermined intervals incorporating random tilts to improve coverage of a view frustum of the virtual camera.

5. The computer-implemented method of claim 1, wherein:
the multiple 2D images comprise one or more RGB (red green blue) images and one or more depth images; and
the multiple 2D images comprise one or more camera parameters.

6. The computer-implemented method of claim 1, wherein the rendering comprises:
processing the multiple 2D images using a recognition model, wherein the recognition model assigns multiple tags to each of the multiple 2D images;
aggregating the multiple tags into an aggregated tag list; and
compiling a list of class labels from the aggregated tag list based on tag frequencies, word similarities, and parts of speech.

7. The computer-implemented method of claim 1, wherein the segmenting the multiple 2D images comprises:
detecting one or more objects using an open vocabulary image segmentation model, wherein:
inputs to the open vocabulary segmentation model comprise the multiple 2D images and a text prompt;
a bounding box is generated for each detected object;
processing, using a segmenting model, the multiple 2D images and the bounding boxes to produce individual pixel masks, wherein:
inputs to the segmenting model comprise the bounding boxes as box prompts;
each individual pixel mask highlights a most prominent detected object within each bounding box;
associating each individual pixel mask with the text prompt that corresponds; and
amalgamating the individual pixel masks to form the semantic segmentation mask.

8. The computer-implemented method of claim 1, wherein the segmenting the classified point cloud utilizes region growing segmentation.

9. The computer-implemented method of claim 1, further comprising:
performing heuristic post processing comprising:
determining a geometric based classification rule;
for each of the geometric segments, evaluating the geometric based classification rule, wherein the evaluating:
determines that at least one of the majority classification labels violates the geometric based classification rule;
based on the violation, labeling the violating majority classification as invalid; and
repeating the geometric segmentation voting wherein the invalid majority classification does not contribute in the voting.

10. The computer-implemented method of claim 1, further comprising:
visualizing the final point cloud as a 3D model of a real world environment in a computer-aided design (CAD) application, wherein the visualization comprises a floor plan for a structure.

11. A computer-implemented system for segmenting a first point cloud, comprising:
(a) a computer having a memory;
(b) a processor executing on the computer;
(c) the memory storing a set of instructions, wherein the set of instructions, when executed by the processor cause the processor to perform operations comprising:
(i) acquiring the first point cloud;
(ii) rendering the first point cloud into multiple two-dimensional (2D) images;
(iii) segmenting the multiple 2D images to generate a semantic segmentation mask, wherein the semantic segmentation mask comprises a per pixel label for each pixel of the multiple 2D images;
(iv) backprojecting the multiple 2D images into a second point cloud, wherein:
(A) the second point cloud comprises a three-dimensional (3D) point cloud;
(B) the second point cloud comprises a classified point cloud;
(C) every point of the classified point cloud comprises a classification label based on the per pixel label from the semantic segmentation mask;
(v) segmenting the classified point cloud into geometric segments;
(vi) performing geometric segmentation voting comprising:
(A) iterating through each of the geometric segments;
(B) for each of the geometric segments, gathering the classification labels associated with that geometric segment;
(C) for each of the geometric segments, determining a majority classification label, wherein the majority classification label has a majority compared to minority classification labels of the gathered classification labels;
(D) reassigning minority classification labels to the majority classification label; and
(vii) exporting a final point cloud with the reassigned minority classification labels as a segmented classified point cloud.

12. The computer-implemented system of claim 11, wherein:
the point cloud is acquired from multiple LiDAR (light detection and ranging) scans; and
the point cloud comprises depth image data for each point in the point cloud.

13. The computer-implemented system of claim 12, wherein:
the first point cloud is for a structured scene;
LiDAR locations are known;
a virtual camera's center is set at fixed points based on the LiDAR locations.

14. The computer-implemented system of claim 12, wherein:
the first point cloud is for an unstructured scene;
determining a virtual camera's position; and
rotating the virtual camera along an XY plane at predetermined intervals incorporating random tilts to improve coverage of a view frustum of the virtual camera.

15. The computer-implemented system of claim 11, wherein:
the multiple 2D images comprise one or more RGB (red green blue) images and one or more depth images; and
the multiple 2D images comprise one or more camera parameters.

16. The computer-implemented system of claim 11, wherein the rendering comprises:
processing the multiple 2D images using a recognition model, wherein the recognition model assigns multiple tags to each of the multiple 2D images;
aggregating the multiple tags into an aggregated tag list; and
compiling a list of class labels from the aggregated tag list based on tag frequencies, word similarities, and parts of speech.

17. The computer-implemented system of claim 11, wherein the segmenting the multiple 2D images comprises:
detecting one or more objects using an open vocabulary image segmentation model, wherein:
inputs to the open vocabulary segmentation model comprise the multiple 2D images and a text prompt;
a bounding box is generated for each detected object;
processing, using a segmenting model, the multiple 2D images and the bounding boxes to produce individual pixel masks, wherein:
inputs to the segmenting model comprise the bounding boxes as box prompts;
each individual pixel mask highlights a most prominent detected object within each bounding box;
associating each individual pixel mask with the text prompt that corresponds; and
amalgamating the individual pixel masks to form the semantic segmentation mask.

18. The computer-implemented system of claim 11, wherein the segmenting the classified point cloud utilizes region growing segmentation.

19. The computer-implemented system of claim 11, further comprising:
performing heuristic post processing comprising:
determining a geometric based classification rule;
for each of the geometric segments, evaluating the geometric based classification rule, wherein the evaluating:
determines that at least one of the majority classification labels violates the geometric based classification rule;
based on the violation, labeling the violating majority classification as invalid; and
repeating the geometric segmentation voting wherein the invalid majority classification does not contribute in the voting.

20. The computer-implemented system of claim 11, further comprising:
visualizing the final point cloud as a 3D model of a real world environment in a computer-aided design (CAD) application, wherein the visualization comprises a floor plan for a structure.
